(19) United States
(12) Patent Application Publication
(10) Pub. No.: US 2025/0246406 A1
(43) Pub. Date: Jul. 31, 2025

(54) FEEDBACK CONTROL SYSTEMS FOR IMPEDANCE MATCHING

(71) Applicant: Lam Research Corporation, Fremont, CA (US)

(72) Inventors: Sina Dehghan, Portland, OR (US); Paul Konkola, West Linn, OR (US); Stephen Topping, Portland, OR (US); Karl Frederick Leeser, West Linn, OR (US)

(21) Appl. No.: 18/847,308

(22) PCT Filed: May 20, 2022
(86) PCT No.: PCT/US2022/030252

§ 371 Date: Sep. 16, 2024

Related U.S. Application Data
(60) Provisional application No. 63/269,600, filed on Mar. 18, 2022.

(51) Int. Cl. H01J 37/32

(52) U.S. Cl. CPC H01J 37/32183; H01J 37/32926; H01J 37/3299

(57) ABSTRACT

Methods, systems, and media for feedback control systems for impedance matching are described. A computer program product for an impedance matching and power distribution network is disclosed. The computer program product may comprise computer-executable instructions which may cause obtaining, at a present time, present values of variable reactances associated with a station of a process chamber, wherein the variable reactances are associated with a first feedback control system for performing impedance matching for the process chamber, and wherein frequency tuning is being performed on an RF generator of the process chamber in association with a second feedback control system for performing impedance matching for the process chamber. The instructions may cause determining updated values of the variable reactances for the station to be utilized in connection with the first feedback control system based at least in part on an error associated with the second feedback control system.

### INCORPORATION BY REFERENCE

A PCT Request Form is filed concurrently with this specification as part of the present application. Each application that the present application claims benefit of or priority to as identified in the concurrently filed PCT Request Form is incorporated by reference in its entirety and for all purposes.

### BACKGROUND

Plasma-based operations may be utilized for semiconductor fabrication. Plasma may be generated using an radio frequency (RF) generator that provides an RF signal to a process chamber. Because a load impedance may vary during various time points, there may be variations in the amount of reflected power. Moreover, in instances in which multiple stations are associated with the process chamber, there may be variations in an amount of power delivered to each station. However, it can be difficult to design feedback control systems that perform impedance matching with the goal of minimizing reflected power and/or controlling a power balance of RF power delivered to each station.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor implicitly admitted as prior art against the present disclosure.

### SUMMARY

Disclosed herein are systems, methods, and media for feedback control systems for impedance matching.

In accordance with some embodiments, a computer program product for an impedance matching and power distribution network may comprise a non-transitory computer-readable medium on which is provided computer-executable instructions. The computer-executable instructions may cause obtaining, at a present time, present values of variable reactances associated with a station of a process chamber, wherein the variable reactances are associated with a first feedback control system for performing impedance matching for the process chamber, and wherein frequency tuning is being performed on an RF generator of the process chamber in association with a second feedback control system for performing impedance matching for the process chamber. The computer-executable instructions may cause determining updated values of the variable reactances for the station to be utilized in connection with the first feedback control system based at least in part on an error associated with the second feedback control system.

In some examples, the error associated with the second feedback control system comprises a difference between a measured frequency at the station and a target frequency associated with the process chamber. In some examples, the frequency at the station is determined using one or more sensing circuits.

In some examples, the updated values of the variable reactances are usable to modify positions of one or more variable reactance elements associated with the process chamber to minimize reflected power associated with the station. In some examples, the one or more variable reactance elements comprise at least one of: a series capacitor, or a shunt capacitor. In some examples, modifying the positions of the one or more variable reactance elements associated with the first feedback control system causes the second feedback control system to drive the frequency toward a target frequency. In some examples, the target frequency corresponds to a frequency specified for a step of a recipe performed at the present time.

In some examples, the computer-executable instructions further cause determining positions of one or more variable reactance elements using a calibration table and based at least in part on the updated values of the variable reactances.

In some examples, the variable reactances comprise a series reactance associated with the station of the process chamber.

In some examples, the variable reactances comprise a shunt reactance associated with the process chamber.

In some examples, the variable reactances comprise a variable series reactance, and wherein an updated series reactance is determined based on a correction to a target series reactance, wherein the correction incorporates the error associated with the second feedback control system.

In some examples, the variable reactances comprise a variable shunt reactance, and wherein an updated shunt reactance is determined without determining a target shunt reactance and based at least in part on the error associated with the second feedback control system.

In some examples, the updated values of the variable reactances are utilized by the first feedback control system responsive to one or more criteria being met. In some examples, the one or more criteria comprise: a reflected power associated with the process chamber exceeding a reflected power threshold, a power balance ratio associated with a plurality of stations of the process chamber exceeding a power balance threshold, and the error associated with the second feedback control system exceeding an error threshold. In some examples, the updated values of the variable reactances are modified prior to use responsive to a determination that a difference between the present values of the variable reactances and the updated values of the variable reactances are within a dither threshold.

In some examples, the determining the updated values of the variable reactances for the station based at least in part on the error associated with the second feedback control system is responsive to a determination that a mode associated with controlling the first feedback control system based on the error associated with the second feedback control system has been activated in a recipe being utilized at the present time.

### BRIEF DESCRIPTION OF THE DRAWINGS

FIG. 1A is a schematic diagram of an example apparatus in accordance with some embodiments.

FIG. 1B is a block diagram showing various components of a system utilized to perform a semiconductor fabrication process in accordance with some embodiments.

FIG. 1C is a block diagram showing various components of a system utilized to perform a semiconductor fabrication process in accordance with some embodiments.

FIG. 2 is a diagram showing various circuit elements utilized in feedback control systems in accordance with some embodiments.

FIG. 3 is a flowchart of an example process for determining values of variable reactance elements to coordinate two feedback control system for impedance matching in accordance with some embodiments.

FIG. 4 is a flowchart of an example process for determining if variable reactances are to be modified in accordance with a feedback control system for impedance matching according to some embodiments.

FIG. 5 is a flowchart of an example process for coordinating two feedback control systems for impedance matching in accordance with some embodiments.

FIG. 6 presents an example computer system that may be employed to implement certain embodiments described herein.

### DETAILED DESCRIPTION

### Terminology

The following terms are used throughout the instant specification:

The terms “semiconductor wafer,” “wafer,” “substrate.” “wafer substrate” and “partially fabricated integrated circuit” may be used interchangeably. Those of ordinary skill in the art understand that the term “partially fabricated integrated circuit” can refer to a semiconductor wafer during any of many stages of integrated circuit fabrication thereon. A wafer or substrate used in the semiconductor device industry typically has a diameter of 200 mm, or 300 mm, or 450 mm. Besides semiconductor wafers, other work pieces that may take advantage of the disclosed embodiments include various articles such as printed circuit boards, magnetic recording media, magnetic recording sensors, mirrors, optical elements, display devices or components such as backplanes for pixelated display devices, flat-panel displays, micro-mechanical devices and the like. The work piece may be of various shapes, sizes, and materials.

A “semiconductor device fabrication operation” as used herein is an operation performed during fabrication of semiconductor devices. Typically, the overall fabrication process includes multiple semiconductor device fabrication operations, each performed in its own semiconductor fabrication tool such as a plasma reactor, an electroplating cell, a chemical mechanical planarization tool, a wet etch tool, and the like. Categories of semiconductor device fabrication operations include subtractive processes, such as etch processes and planarization processes, and material additive processes, such as deposition processes (e.g., physical vapor deposition, chemical vapor deposition, atomic layer deposition, electrochemical deposition, electroless deposition). In the context of etch processes, a substrate etch process includes processes that etch a mask layer or, more generally, processes that etch any layer of material previously deposited on and/or otherwise residing on a substrate surface. Such an etch process may etch a stack of layers in the substrate.

“Manufacturing equipment” refers to equipment in which a manufacturing process takes place. Manufacturing equipment often has a process chamber in which the workpiece resides during processing. Typically, when in use, manufacturing equipment performs one or more semiconductor device fabrication operations. Examples of manufacturing equipment for semiconductor device fabrication include deposition reactors such as electroplating cells, physical vapor deposition reactors, chemical vapor deposition reactors, and atomic layer deposition reactors, and subtractive process reactors such as dry etch reactors (e.g., chemical and/or physical etch reactors), wet etch reactors, and ashers.

### Impedance Matching Feedback Control Systems

Plasma-based reactors may be utilized to perform plasma-based semiconductor operations (e.g., plasma-based deposition and/or plasma-based etching). Such a reactor, or process chamber, may have multiple (e.g., two, four, eight, sixteen, etc.) stations. An RF generator may provide an RF signal to the station(s) of the process chamber, where the RF signal is used to generate plasma within the station to perform the plasma-based operation. In cases in which a process chamber utilizes multiple stations, a power divider may be used to provide the power to the multiple stations. A matching network may be utilized to perform impedance matching, for example, to account for changes in the load impedance. Such a matching network (e.g., to perform impedance matching) may allow maximum power to be transferred from the RF generator to each of the stations by eliminating reflected power.

In some cases, the matching network may utilize a first feedback control system that tunes one or more variable reactance elements in order to perform impedance matching. The one or more variable reactance elements may include variable capacitors, variable inductors or the like. In some cases, the variable reactance elements may be adjusted in position to achieve a target, or desired reactance value that has been calculated as one that will eliminate reflected power. A system may additionally utilize a second feedback control system that performs frequency tuning on an RF generator of the process chamber to perform impedance matching. Because impedance matching (i.e., to minimize or eliminate reflected power) requires manipulating two independent dimensions (i.e., the real and imaginary components of the impedance), adjusting frequency alone allows one dimension to be tuned to a desire value, but does not necessarily allow both independent dimensions to be adjusted to desired values. Accordingly, frequency tuning may allow reflected power to be reduced, but not necessarily eliminated. Because adjusting the variable reactance elements (e.g., via a stepper motor) may require a time duration on the order of milliseconds, or tens of milliseconds, the first feedback control system may be relatively slow. By contrast, frequency tuning may be faster than tuning variable reactance elements, for example, on the order of microseconds or tens of microseconds. In other words, the first feedback control system that utilizes tuning of variable reactance elements may enable complete elimination of reflected power while being relatively slow, while the second feedback control system that utilizes frequency tuning may provide only a reduction in reflected power while being orders of magnitude faster than the first feedback control system.

Described herein are techniques for coordinating a first feedback control system that utilizes tuning of variable reactance elements with a second feedback control system that performs frequency tuning on an RF generator. In particular, new or updated values of reactance elements of the first feedback control system may be determined based on an error of the second feedback control system. In some implementations, the error may be a difference between measured frequencies at each station of the process chamber (or an average of measured frequencies across the stations) and a target frequency. By coordinating the first feedback control system with the second feedback control system, advantages of each feedback control system may be combined, thereby allowing faster elimination of reflected power. The techniques described herein may be particularly advantageous at recipe step changes in which RF signal characteristics are to be changed in a stepped manner (e.g., with a discontinuity in one or more parameters). Moreover, at steady-state portions during a recipe step, the techniques described herein may enable driving of frequencies at each station toward the target frequency specified in the recipe step.

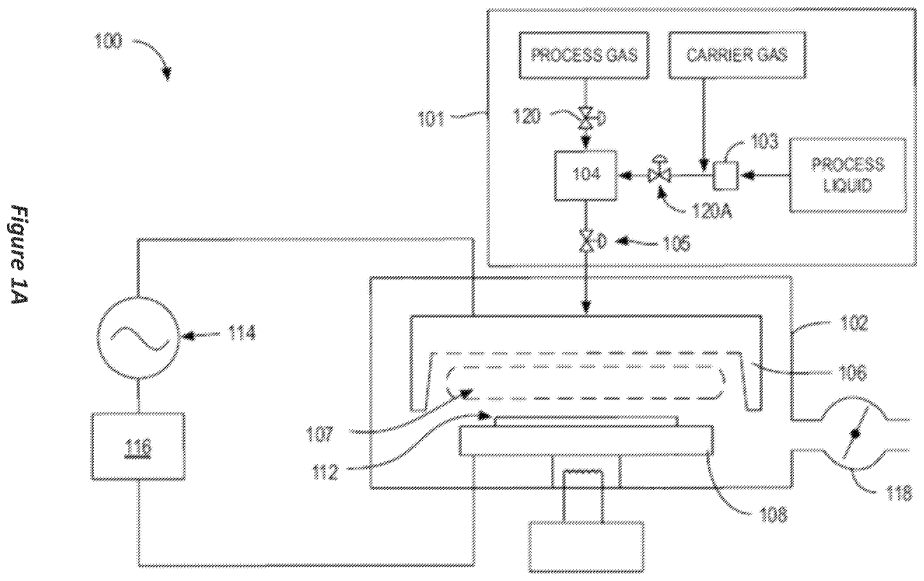

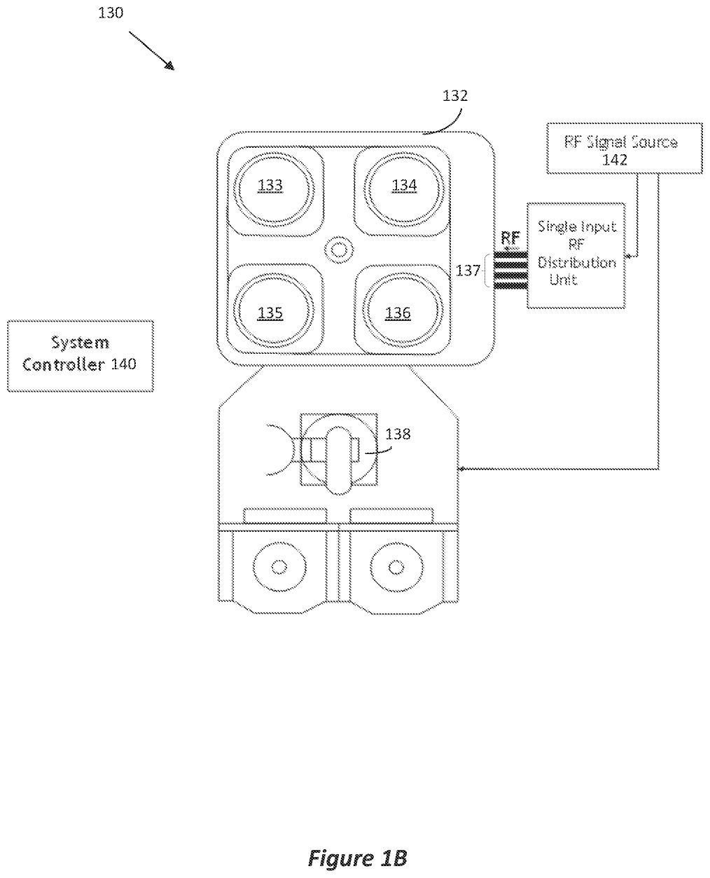

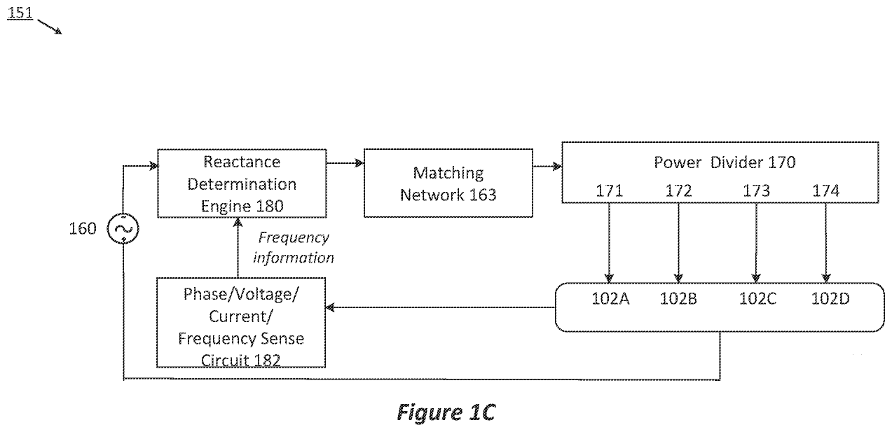

FIG. 1A shows a substrate processing apparatus for depositing films on semiconductor substrates using any number of processes. The apparatus 100 of FIG. 1A utilizes single processing station 102 of a process chamber with a single substrate holder 108 (e.g., a pedestal) in an interior volume which may be maintained under vacuum by vacuum pump 118. Also fluidically coupled to the process chamber for the delivery of (for example) film precursors, carrier and/or purge and/or process gases, secondary reactants, etc. is gas delivery system 101 and showerhead 106. Equipment for generating plasma within the process chamber is also shown in FIG. 1A. The apparatus schematically illustrated in FIG. 1 may be adapted for performing, in particular, plasma-enhanced CVD.

For simplicity, processing apparatus 100 is depicted as a standalone process station (102) of a process chamber for maintaining a low-pressure environment. However, it will be appreciated that a plurality of process stations may be included in a common process tool environment—e.g., within a common reaction chamber—as described herein. For example, FIG. 1C depicts an implementation of a multi-station processing tool and is discussed in further detail below. Further, it will be appreciated that, in some implementations, one or more hardware parameters of processing apparatus 100, including those discussed in detail herein, may be adjusted programmatically by one or more system controllers.

Station 102 of the process chamber fluidically communicates with gas delivery system 101 for delivering process gases, which may include liquids and/or gases, to a distribution showerhead 106. Gas delivery system 101 includes a mixing vessel 104 for blending and/or conditioning process gases for delivery to showerhead 106. One or more mixing vessel inlet valves 120 may control introduction of process gases to mixing vessel 104.

Some reactants may be stored in liquid form prior to vaporization and subsequent delivery to station 102 of a process chamber. The implementation of FIG. 1A includes a vaporization point 103 for vaporizing liquid reactant to be supplied to mixing vessel 104. In some implementations, vaporization point 103 may be a heated liquid injection module. In some other implementations, vaporization point 103 may be a heated vaporizer. In yet other implementations, vaporization point 103 may be eliminated from the process station. In some implementations, a liquid flow controller (LFC) upstream of vaporization point 103 may be provided for controlling a mass flow of liquid for vaporization and delivery to processing station 102.

Showerhead 106 distributes process gases and/or reactants (e.g., film precursors) toward substrate 112 at the process station, the flow of which is controlled by one or more valves upstream from the showerhead (e.g., valves 120, 120A, 105). In the implementation shown in FIG. 1A, substrate 112 is located beneath showerhead 106, and is shown resting on a pedestal 108. Showerhead 106 may have any suitable shape and may have any suitable number and arrangement of ports for distributing process gases to substrate 112. In some implementations with two or more stations, gas delivery system 101 includes valves or other flow control structures upstream from the showerhead, which can independently control the flow of process gases and/or reactants to each station such that gas may be flowed to one station but not another. Furthermore, gas delivery system 101 may be configured to independently control the process gases and/or reactants delivered to each station in a multi-station apparatus such that the gas composition provided to different stations is different; e.g., the partial pressure of a gas component may vary between stations at the same time.

A volume 107 is located beneath showerhead 106. In some implementations, pedestal 108 may be raised or lowered to expose substrate 112 to volume 107 and/or to vary a volume of volume 107. Optionally, pedestal 108 may be lowered and/or raised during portions of the deposition process to modulate process pressure, reactant concentration, etc., within volume 107.

In FIG. 1A, showerhead 106 and pedestal 108 are electrically coupled to radio frequency power supply 114 and matching network 116 for powering a plasma generator. In some implementations, the plasma energy may be controlled (e.g., via a system controller having appropriate machine-readable instructions and/or control logic) by controlling one or more of a process station pressure, a gas concentration, a source of RF power, and so forth. For example, radio frequency power supply 114 and matching network 116 may be operated at any suitable power to form plasma having a desired composition of radical species. Likewise, RF power supply 114 may provide RF power of any suitable frequency, or group of frequencies, and power.

In some implementations, the plasma ignition and maintenance conditions are controlled with appropriate hardware and/or appropriate machine-readable instructions in a system controller which may provide control instructions via a sequence of input/output control (IOC) instructions. In one example, the instructions for setting plasma conditions for plasma ignition or maintenance are provided in the form of a plasma activation recipe of a process recipe. In some cases, process recipes may be sequentially arranged, so that all instructions for a process are executed concurrently with that process. In some implementations, instructions for setting one or more plasma parameters may be included in a recipe preceding a plasma process. For example, a first recipe may include instructions for setting a flow rate of an inert (e.g., helium) and/or a reactant gas, instructions for setting a plasma generator to a power set point, and time delay instructions for the first recipe. A second, subsequent recipe may include instructions for enabling the plasma generator and time delay instructions for the second recipe. A third recipe may include instructions for disabling the plasma generator and time delay instructions for the third recipe. It will be appreciated that these recipes may be further subdivided and/or iterated in any suitable way within the scope of the present disclosure.

In some deposition processes, plasma strikes last on the order of a few seconds or more in duration. In certain implementations described herein, much shorter plasma strikes may be applied during a processing cycle. These may be on the order of less than 50 milliseconds, such as 25 milliseconds.

For simplicity, processing apparatus 100 is depicted in FIG. 1A as a standalone station (102) of a process chamber for maintaining a low-pressure environment. However, it may be appreciated that a plurality of process stations may be included in a multi-station processing tool environment, such as shown in FIG. 1B, which depicts a schematic view of an embodiment of a multi-station processing tool.

Processing apparatus 130 employs an integrated circuit fabrication chamber 132 that includes multiple fabrication process stations, each of which may be used to perform processing operations on a substrate held in a wafer holder, such as pedestal 108 of FIG. 1A, at a particular process station. In the embodiment of FIG. 1B, the integrated circuit fabrication chamber 132 is shown having four process stations, 133, 134, 135, and 136, as well as 4 cables, which provide RF power to each of the four process stations through input ports 137. Other similar multi-station processing apparatuses may have more or fewer process stations depending on the implementation and, for example, a desired level of parallel wafer processing, size/space constraints, cost constraints, etc. Also shown in FIG. 1B is substrate handler robot 138, which may operate under the control of system controller 140, configured to move substrates from a wafer cassette (not shown in FIG. 1B) from a loading port and into integrated circuit fabrication chamber 132, and onto one of process stations 133, 134, 135, or 136.

FIG. 1B also depicts an embodiment of a system controller 140 employed to control process conditions and hardware states of processing apparatus 130. System controller 140 may include one or more memory devices, one or more mass storage devices, and one or more processors. The one or more processors may include a central processing unit, analog and/or digital input/output connections, stepper motor controller boards, etc. In some embodiments, system controller 140 controls all of the activities of processing tool 130. System controller 140 executes system control software stored in a mass storage device, which may be loaded into a memory device, and executed on a hardware processor of the system controller. Software to be executed by a processor of system controller 140 may include instructions for controlling the timing, mixture of gases, fabrication chamber and/or station pressure, fabrication chamber and/or station temperature, wafer temperature, substrate pedestal, chuck and/or susceptor position, number of cycles performed on one or more substrates, and other parameters of a particular process performed by processing tool 130. These programed processes may include various types of processes including, but not limited to, processes related to determining an amount of accumulation on a surface of the chamber interior, processes related to deposition of film on substrates including numbers of cycles, and processes related to cleaning the chamber. System control software, which may be executed by one or more processors of system controller 140, may be configured in any suitable way. For example, various process tool component subroutines or control objects may be written to control operation of the process tool components necessary to carry out various tool processes.

In some embodiments, software for execution by way of a processor of system controller 140 may include input/output control (IOC) sequencing instructions for controlling the various parameters described above. For example, each phase of deposition and deposition cycling of a substrate may include one or more instructions for execution by system controller 140. The instructions for setting process conditions for an ALD/CFD deposition process phase may be included in a corresponding ALD/CFD deposition recipe phase. In some embodiments, the recipe phases may be sequentially arranged, so that all instructions for a process phase are executed concurrently with that process phase.

Other computer software and/or programs stored on a mass storage device of system controller 140 and/or a memory device accessible to system controller 140 may be employed in some embodiments. Examples of programs or sections of programs for this purpose include a substrate positioning program, a process gas control program, a pressure control program, a heater control program, and a plasma control program. A substrate positioning program may include program code for process tool components that are used to load the substrate onto pedestal 108 (of FIG. 1A) and to control the spacing between the substrate and other parts of processing apparatus 130. A positioning program may include instructions for appropriately moving substrates in and out of the reaction chamber as necessary to deposit films on substrates and clean the chamber.

A process gas control program may include code for controlling gas composition and flow rates and optionally for flowing gas into one or more process stations prior to deposition in order to stabilize the pressure in the process station. In some embodiments, the process gas control program includes instructions for introducing gases during formation of a film on a substrate in the reaction chamber. This may include introducing gases for a different number of cycles for one or more substrates within a batch of substrates. A pressure control program may include code for controlling the pressure in the process station by regulating, for example, a throttle valve in the exhaust system of the process station, a gas flow into the process station, etc. The pressure control program may include instructions for maintaining the same pressure during the deposition of differing number of cycles on one or more substrates during the processing of the batch.

A heater control program may include code for controlling the current to a heating unit that is used to heat the substrate. Alternatively, the heater control program may control delivery of a heat transfer gas (such as helium) to the substrate.

In some embodiments, there may be a user interface associated with system controller 140. The user interface may include a display screen, graphical software displays of the apparatus and/or process conditions, and user input devices such as pointing devices, keyboards, touch screens, microphones, etc.

In some embodiments, parameters adjusted by system controller 140 may relate to process conditions. Non-limiting examples include process gas composition and flow rates, temperature, pressure, plasma conditions, etc. These parameters may be provided to the user in the form of a recipe, which may be entered utilizing the user interface. The recipe for an entire batch of substrates may include compensated cycle counts for one or more substrates within the batch in order to account for thickness trending over the course of processing the batch.

Signals for monitoring the process may be provided by analog and/or digital input connections of system controller 140 from various process tool sensors. The signals for controlling the process may be output by way of the analog and/or digital output connections of processing tool 130. Non-limiting examples of process tool sensors that may be monitored include mass flow controllers, pressure sensors (such as manometers), thermocouples, etc. Sensors may also be included and used to monitor and determine the accumulation on one or more surfaces of the interior of the chamber and/or the thickness of a material layer on a substrate in the chamber. Appropriately programmed feedback and control algorithms may be used with data from these sensors to maintain process conditions.

System controller 140 may provide program instructions for implementing the above-described deposition processes. The program instructions may control a variety of process parameters, such as DC power level, pressure, temperature, number of cycles for a substrate, amount of accumulation on at least one surface of the chamber interior, etc. The instructions may control the parameters to operate in-situ deposition of film stacks according to various embodiments described herein.

For example, the system controller may include control logic for performing the techniques described herein, such as determining an amount of accumulated deposition material currently on at least an interior region of the deposition chamber interior, applying the determine the amount of deposited material, or a parameter derived therefrom, to a relationship between (i) a number of ALD cycles required to achieve a target deposition thickness, and (ii) a variable representing an amount of accumulated deposition material, in order to obtain a compensated number of ALD cycles for producing the target deposition thickness given the amount of accumulated deposition material currently on the interior region of the deposition chamber interior, and performing the compensated number of ALD cycles on one or more substrates in the batch of substrates. The system may also include control logic for determining that the accumulation in the chamber has reached an accumulation limit and stopping the processing of the batch of substrates in response to that determination, and for causing a cleaning of the chamber interior.

In addition to the above-identified functions and/or operations performed by system controller 140 of FIG. 1B, the controller may additionally control and/or manage the operations of an RF subsystem, which may generate and convey RF power to integrated circuit fabrication chamber 132 via radio frequency input ports 137. As described further herein, such operations may relate to, for example, determining upper and lower thresholds for RF power to be delivered to integrated circuit fabrication chamber 132, determining actual (such as real-time) levels of RF power delivered to integrated circuit fabrication chamber 132, RF power activation/deactivation times, RF power on/off duration, operating frequency, and so forth.

In particular embodiments, integrated circuit fabrication chamber 132 may comprise input ports in addition to input ports 137 (additional input ports not shown in FIG. 1B). Accordingly, integrated circuit fabrication chamber 132 may utilize 8 RF input ports. In particular embodiments, process stations 133-136 of integrated circuit fabrication chamber 132 may each utilize first and second input ports in which a first input port may convey a signal having a first frequency and in which a second input port may convey a signal having a second frequency. Use of dual frequencies may bring about enhanced plasma characteristics, which may give rise to deposition rates within particular limits and/or more easily controlled deposition rates. Dual frequencies may bring about other desirable consequences other than those described herein. In certain embodiments, frequencies of between about 300 KHz and about 300 MHz may be utilized.

In FIG. 1B, RF power from a RF signal source 142 may be split among four output channels, which may be coupled to a corresponding one of input port 137 of integrated circuit fabrication chamber 132. In at least particular embodiments, it may be useful for RF power from a RF signal source 142 to be split into relatively equal portions (such as about +1%). Thus, in an example, if RF signal source 142 provides an output power of 1000 W, about 250 W (+1%) is conveyed to each of input port 137 of fabrication chamber 132.

FIG. 1C is a block diagram showing various components of a system utilized to perform a semiconductor fabrication process, according to an implementation 151. In FIG. 1C, RF signal generator 160 is utilized to generate an excitation signal, which may bring about formation of a plasma within stations 102A, 102B, 102C, and 102D of the process chamber. Stations 102A, 102B, 102C, and 102D may correspond to stations of a semiconductor process chamber, as previously described in reference to FIG. 1A. Note that, in some implementations, multiple RF signal generators may be used, such as a first RF generator configured to generate a relatively low-frequency signal, such as a signal of approximately 400 kHz, and a second RF generator configured to generate a relatively high-frequency signal, such as a signal of approximately 27.12 MHz. It should be noted, however, that these represent merely example frequencies. In other implementations, differing radio frequencies may be generated, and implementations are not limited to 400 kHz and 27.12 MHz signals. For example, in particular instances, a relatively low-frequency may correspond to a frequency of between 360 kHz and 440 kHz. In another instance, a relatively high-frequency may correspond to a frequency of between 26.5 MHz and 27.5 MHz.

In FIG. 1C, an RF transmission line couples RF signal generator 160 to matching network 163. The RF transmission line may involve a characteristic impedance of about 50 ohms. However, other implementations may utilize transmission lines having differing characteristic impedances, such as 70 ohms, 300 ohms, and so forth. In the implementation of FIG. 1C, matching network 163 operates to match the load presented by power divider 170 to the output impedance of RF signal generator 160. Such matching brings about an ability to couple maximum power transfer from RF signal generator 160 to power divider 170. Accordingly, even when power divider 170 presents a highly reactive load (e.g., a complex impedance having a relatively small real component and a large reactive component) maximum power can be transferred from RF signal generator 160 to power divider 170. Matching network 163 may utilize various reactive components, such as inductors and/or capacitors, which operate to compensate for the highly reactive load that may be presented by power divider 170. It should be noted that, in some implementations, matching network 163 and power divider 170 may be combined in an integrated system.

In particular implementations, components of matching network 163 may be arranged so as to match a particular load presented by low-frequency and high-frequency input ports of power divider 170, which may operate to provide plasma-generating power via output ports 171, 172, 173 and 174. However, during plasma-based etching operations or during other plasma-based processes (for example), a load, such as a reactive load presented by the formation of plasma within stations 102A, 102B, 102C, and 102D of a process chamber, may begin to vary or drift. Accordingly, for example, during the initial moments of plasma generation (e.g., the initial 30-60 seconds) output signal amplitudes from ports 171-174 may correspond to substantially equal quantities. However, as plasma generation progresses, output signal amplitudes from ports 171-174 may begin to differ. Such differences may be brought about by changes in reactive loads presented by stations 102A-102D of the process chamber. Thus, in some instances, in response to varying reactive loads presented by stations 102A-102D of the process chamber, actual power coupled from power divider ports 171-174 may vary by values ranging from 0.0% to 100.0% and subject to the constraint that the sum of power going to each station adds to 100% Additionally, RF power flow to a station can be set to 0.0, or other negligible amount, by way of entering 0.0 Watt as a setpoint. Alternatively, capacitance of a variable capacitor may be adjusted to a value that brings about a current flow that approaches or approximates 0.0 Ampere.

It may be difficult to ensure constant, uniform power transfer from power divider 170 to stations 102A-102D. In some implementations (e.g, in instances in which a matching network and power divider are integrated), a first feedback control system may operate to provide real-time, closed-loop tuning of reactance components within matching network 163 in response to variances in reactive loads presented by stations 102A-102D. In some embodiments, the first feedback control system may tune one or more reactance components or elements within matching network 163 by adjusting positions of the one or more reactance components (e.g., variable capacitors, or the like). Such position adjustments may be implemented by one or more stepper motors. The first feedback control system may provide substantial, or full, control to minimize reflected power and/or to balance power delivered to each station.

In some implementations, a second feedback control system may operate to provide frequency tuning on RF signal generator 160 as part of a second impedance matching control system. Because the second feedback control system adjusts frequency, and therefore, may only be able to optimize a single dimension of impedance toward a desired or target value, the second feedback control system may be able to reduce reflected power without eliminating reflected power.

Because the first feedback control system may utilize tuning of reactance components, the first feedback control system may operate on a slower time scale relative to the second feedback control system. For example, the first feedback control system may make adjustments on a scale of tens or hundreds of milliseconds, while the second feedback control system may operate on a scale of microseconds. In other words, the first feedback control system may be able to more accurately and fully perform impedance matching, reflected power minimization, and power balance relative to the second feedback control system, albeit on a slower time scale than the second feedback control system. The longer time scales required by the first feedback control system may be particularly problematic during step changes in a recipe where RF signal conditions are adjusted in a step-wise manner.

Described herein are techniques implemented in a first feedback control system (which tunes reactive components) to allow the first feedback control system to operate in coordination with a second feedback control system (which performs frequency tuning). In particular, using the techniques described herein, the first feedback control system may tune reactance components by considering an error of the second feedback control system. The error may be a difference between a measured frequency and a target frequency specified by the recipe being implemented, where the measured frequency corresponds to a frequency that is a result of the frequency tuning being performed by the second feedback control system.

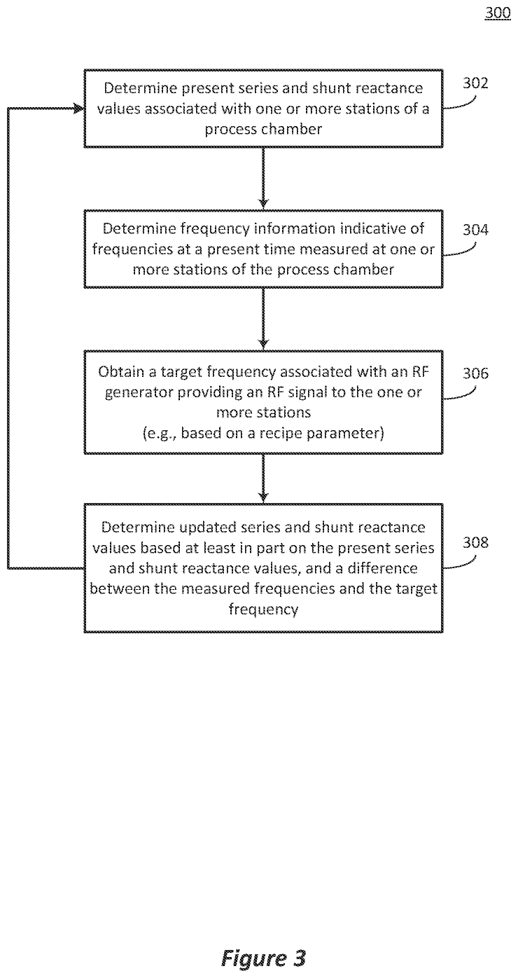

Referring back to FIG. 1C, in some implementations, a reactance determination engine 180 may provide input to matching network 163 that indicates reactance values to be utilized by matching network 163 to perform impedance matching using the first feedback control system. In some implementations, reactance determination engine 180 may receive phase, voltage, current, and/or frequency information from a phase/voltage/current/frequency sense circuit 182. For example, phase/voltage/current/frequency sense circuit 182 may measure a voltage and/or a current at one or more stations of the process chamber. Continuing with this example, reactance determination engine 180 may determine the reactance values based on the voltage and/or current, phase and/or frequency information associated with the RF signal provided to a station. Note that phase/voltage/current/frequency sense circuit is sometimes referred to as a “VI probe” herein. More detailed techniques that may be performed by reactance determination engine 180 are shown in and described below in connection with FIGS. 3, 4, and 5.

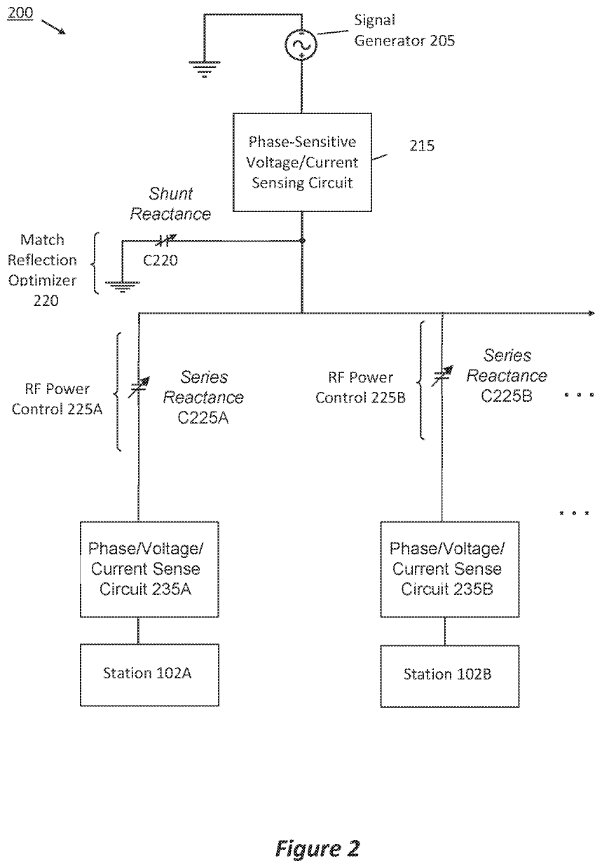

FIG. 2 is a diagram showing various circuit elements utilized in an impedance matching process used in the performance of a plasma-enhanced process, according to an implementation 200. It may be appreciated that any number of, for example, RF power control circuits (e.g., 225A, 225B), phase/voltage/current sensing circuits (e.g., 215, 235A, 235B), and stations (e.g., 102A, 102B) may be utilized.

In FIG. 2, match reflection optimizer 220 includes variable capacitor C220. Although not shown in FIG. 2, match reflection optimizer 220 may include an inductor having a value selected to provide a range of admittances that can be presented by the combination of C220 in series with the inductor. In particular implementations, C220 represents a variable capacitor having a value that can be controlled via a remote signal, such as a signal from a reactance determination engine (e.g., as shown in and described above in connection with FIG. 1C) or other controller. Accordingly, in response to the phase/voltage/current sensing circuit measuring an increase in inductance (e.g., via measurement of a voltage standing wave ratio (VSWR)) presented by the combination of RF power control circuits 225A-225N, a value of capacitance presented by C220 may be adjusted so as to present sufficient admittance to return the measured VSWR to a value below a predetermined threshold (e.g., 1.15:1, 1.10:1, etc.). Such adjustment of capacitors C220 along with any necessary adjustments to other reactive elements (e.g., 225A) may bring about an increase in power transfer from signal generator 205 to stations 102A and 102B.

RF power control circuit 225A may include a series impedance, represented by C225A. RF power control circuit 225A may also include an inductor, which may be a static component having a value selected to provide a range of impedances that can be presented by the combination of C225A and the inductor. In particular implementations, C225A represents a variable capacitor having a value that can be controlled via a remote signal, such as a signal from a reactance determination engine (e.g., as shown in and described above in connection with FIG. 1C). Thus, responsive to phase/voltage/current sensing circuit 235A measuring a change in impedance of station 102A, capacitor C225A may be adjusted, so as to bring about maximum power transfer between the RF generator and stations 102A and 102B. Similar adjustments may be made to variable capacitor C225B based on a signal from phase/voltage/current sensing circuit 235B.

In some implementations, adjustments to a first feedback control system may be made by adjusting variable reactance elements associated with the first feedback control system. Using the techniques described herein, an updated value associated with a variable reactance element may be determined based on a present value of the variable reactance element, an error associated with a second feedback control system that is being used to perform frequency tuning to provide impedance matching for the system, and/or measurements from a VI probe (which may include voltage, current, frequency, and/or phase measurements or determinations). In some embodiments, the error associated with the second feedback control system may be a difference between a measured frequency and a target frequency.

In some implementations, the variable reactance elements may include one or more series reactances, each associated with a particular station of the process chamber (e.g., as shown in and described above in connection with FIG. 2). In some embodiments, an updated series reactance value may be determined based on a present series reactance value and a modified target series reactance value. In some embodiments, the modified target series reactance value may be determined by first determining a target series reactance (generally referred to herein as X_{d}) as a target series reactance that will minimize reflected power for a particular station associated with the series reactance element. The target series reactance may be determined using a circuit model, VI probe measurements (which may include magnitude and/or phase information) from one or more VI probes associated with the station, and a desired power ratio for each station (which may be determined based on a recipe setpoint). The target series reactance value may then be modified to compensate for uncertainties in the circuit model by utilizing an estimate of the present series reactance (generally referred to herein as Xₙ). The estimate of the present series reactance may be determined based on the circuit model, magnitude and/or phase information obtained from one or more VI probes associated with each station, and VI probe measurements (which may include magnitude and/or phase) from a VI probe upstream of the network. The resulting value may then be further modified based on an error associated with the second feedback control system. In particular, the resulting value may be modified based on an error between a measured frequency at the station associated with the series reactance element and a target frequency. The target frequency may be one that is specified by a recipe, such as a target frequency specified by a particular step of the recipe that is being performed or is about to be performed.

In some implementations, the variable reactance elements may include one or more shunt reactances. For example, the one or more shunt reactances may be associated with a match reflection optimizer, as shown in and described above in connection with FIG. 2. In some embodiments, an updated shunt reactance value may be determined based on a present shunt reactance value and an error associated with the second feedback control system. For example, the error associated with the second feedback control system may be the difference between a measured frequency (e.g., an average of the measured frequencies at each station) and a target frequency. The target frequency may be one that is specified by a recipe, such as a target frequency specified by a particular step of the recipe that is being performed or is about to be performed. It should be noted that, in some implementations, when the process chamber is operating in a steady state mode (e.g., not at a step transition in a recipe being executed by the process chamber), tuning a shunt reactance to an updated shunt reactance value may cause the frequency to be driven toward the target frequency, due to consideration of the error in frequency in setting the updated shunt reactance value. Moreover, as will be described below in more detail in connection with FIG. 3, the updated shunt reactance value may be determined without determining a target shunt reactance value and based on the error in frequency, which allows the frequency to be driven toward the target frequency. It should be understood that although the techniques and system described herein generally refer to a shunt reactance being adjusted based on frequency error to drive the frequency towards the target frequency and series reactances being adjusted based on the calculated target reactance, in some implementations, this may be reversed. In other words, in some embodiments, series reactances may be used to drive the frequency to a target frequency, and shunt reactances may be adjusted based on calculated target reactances.

FIG. 3 illustrates a flowchart of an example process 300 for coordinating two feedback control systems for performing impedance matching for a process chamber in accordance with some implementations. It should be noted that blocks of process 300 may be executed by one or more processors and/or one or more controllers associated with the process chamber, as shown in and described above in connection with FIG. 1A. In some embodiments, blocks of process 300 may be performed in an order other than what is shown in FIG. 3. In some embodiments, two or more blocks of process 300 may be performed substantially in parallel. In some embodiments, one or more blocks of process 300 may be omitted.

Process 300 can begin at 302 by determining present series and/or shunt reactance values associated with one or more stations of a process chamber. As shown in and described above in connection with FIG. 2, there may be multiple series control reactance elements, each associated with a station of the process chamber. As shown in and described above in connection with FIG. 2, a shunt reactance element may be associated with all stations of the process chamber. In instances in which a series reactance element is associated with a particular station j, a present series reactance value associated with station j may be represented by Xₛₑᵣ(j). The present shunt reactance value may be represented by Xₛₕᵤ. In some implementations, present series reactance values and/or the present shunt reactance value may be determined using a calibration table or a look up table. For example, in instances in which a reactance element (whether associated with a series reactance or a shunt reactance) is a variable capacitor, the present reactance value (e.g, a present series reactance value and/or the present shunt reactance value) may be determined by utilizing the current position of the variable capacitor as a key to the calibration table to identify a present reactance value associated with the current position.

At 304, process 300 may determine frequency information indicative of frequencies at a present time at one or more stations of the process chamber. In some implementations, the frequency information may include a frequency measured at each station of the process chamber. In some embodiments, the frequency may be measured at a particular station using a VI probe associated with the corresponding station. It should be noted that, in some implementations, the frequency may be measured for only a high frequency (HF) signal provided to the station.

At 306, process 300 may obtain a target frequency associated with an RF generator providing an RF signal to the one or more stations of the process chamber. In some embodiments, the target frequency may be one that is specified by a recipe being implemented by the process chamber, e.g., for a particular step of the recipe. It should be noted that, in instances in which frequency tuning is not being performed (e.g., the second feedback control system is disabled), the target frequency may be identified as the frequency being output by the RF generator. Utilizing the target frequency being output by the RF generator in instances in which frequency tuning is not being performed may allow backward compatibility for implementation of the blocks of process 300 in instances in which frequency tuning is not implemented and/or in which frequency tuning is disabled for a particular recipe or recipe step.

At 308, process 300 can determine updated series and/or shunt reactance values based at least in part on the present series and/or shunt reactance values and a difference between the measured frequencies and the target frequency.

In some implementations, for a particular station j, an updated series reactance value may be determined based on a present series reactance value Xₛₑᵣ(j) for station j (e.g., as determined at block 302), a modified target series reactance value, and a difference between the average of the measured frequencies across the one or more stations and the target frequency (e.g., as determined at block 306, and generally referred to herein as Δf). The modified target series reactance value may be determined by determining a target, or desired series reactance value for the station, represented as X_{d}(j). In some implementations, the target series reactance value for the station may be determined based on a circuit model, VI probe measurements (which may include magnitude and/or phase information) from one or more VI probes associated with the station, and a desired power ratio for each station (which may be determined based on a recipe setpoint). The target series reactance value for the station may then be modified based on an estimate of the present series reactance for the station, represented as Xₙ(j). The estimate of the present series reactance for the station may be determined based on the circuit model, based on measurements from a VI probe associated with the station, and/or based on measurements from a VI probe upstream from the network. The measurements from the VI probe may be utilized to determine magnitude and/or phase information (e.g., associated with the RF signal being provided to the station). Using the measurements from the VI probe to modify the target, or desired, series reactance value may allow compensation for uncertainties in the circuit model.

By way of example, in some embodiments, the updated series reactance value for station j, X_{new_ser}(j), may be determined by:

$${X}_{{new}_{ser}} ( j ) = {X}_{ser} ( j ) + ( 1 - dampX ) * ( {X}_{d} ( j ) - {X}_{n} ( j ) ) + {k}_{ser} * Δ f$$

In the equation above, Xₛₑᵣ (j) represents the present series reactance value for station (e.g., as determined at block 302), X_{d}(j) represents the target, or desired series reactance value for station j, Xₙ(j) represents the estimated present series reactance value for station/determined based on the circuit model and/or VI probe information, and Δf represents a difference between an average of frequencies measured at each of the stations and the target frequency (e.g., as obtained at block 306). Additionally, in the equation above, dampX represents a damping constant, and kₛₑᵣ represents a weighting coefficient that weights an importance of the error of the second feedback control system in updating the series reactance value.

In some implementations, the updated shunt reactance value (generally referred to herein as X_{new_shu}) may be determined based on a present value of the shunt reactance (generally referred to herein as Xₛₕᵤ) and a difference between the average of frequencies measured at each station and the target frequency. By way of example, in some embodiments, the updated shunt reactance value may be determined by:

$${X}_{{new}_{shu}} = {X}_{shu} + {k}_{shu} * Δ f$$

In the equation above, Δf represents a difference between an average of frequencies measured at each of the stations and the target frequency (e.g., as obtained at block 306). Additionally, in the equation above, kₛₕᵤ represents a weighting coefficient that weights an importance of the error of the second feedback control system in updating the shunt reactance value.

It should be noted that the equations given above for determining updated series reactance values and updated shunt reactance values may be switched in an implementation in which the series reactance is used to drive the frequency to the target frequency and in which the shunt reactance is used to drive the reactance to a target reactance.

In some implementations, the updated series reactance value(s) and the updated shunt reactance value(s) are usable to modify positions of variable reactance elements in order to adjust the present series reactance value(s) and/or the present shunt reactance value toward the updated reactance values. For example, an updated reactance value (whether an updated series reactance value or an updated shunt reactance value) may be used as a key to a calibration table or a look up table to identify a position of a variable reactance element (e.g., a variable capacitor) to achieve the updated reactance value. In some implementations, the variable reactance element may then be actuated to the identified position using, e.g., a stepper motor.

In some implementations, an updated series reactance value and/or an updated shunt reactance value may be determined, as described above. In some embodiments, a determination may be made of whether to use the updated series reactance value and/or the updated shunt reactance value (e.g., by adjusting one or more variable reactance elements associated with the process chamber to positions corresponding to the updated reactance values). In some implementations, the updated series reactance values and/or the updated shunt reactance values may be utilized responsive to a determination that one or more criteria are met. The one or more criteria may include: a reflected power associated with the process chamber exceeding a reflected power threshold or outside of a reflected power range, a power balance of power being delivered to two or more stations of the process chamber exceeding a power balance threshold or being outside of a power balance range, and an error associated with the second feedback control system exceeding an error threshold or being outside of an error range. It should be noted that, in some cases, in instances in which the reflected power is within a reflected power range, a power balance is within a power balance range, and an error associated with the second feedback control system is within an error range, but there are differences between an updated reactance value and the present reactance value, reactance element (e.g, capacitor) positions may be maintained to avoid unnecessarily dithering the reactance elements, which may avoid unnecessary wear and tear on the reactance elements.

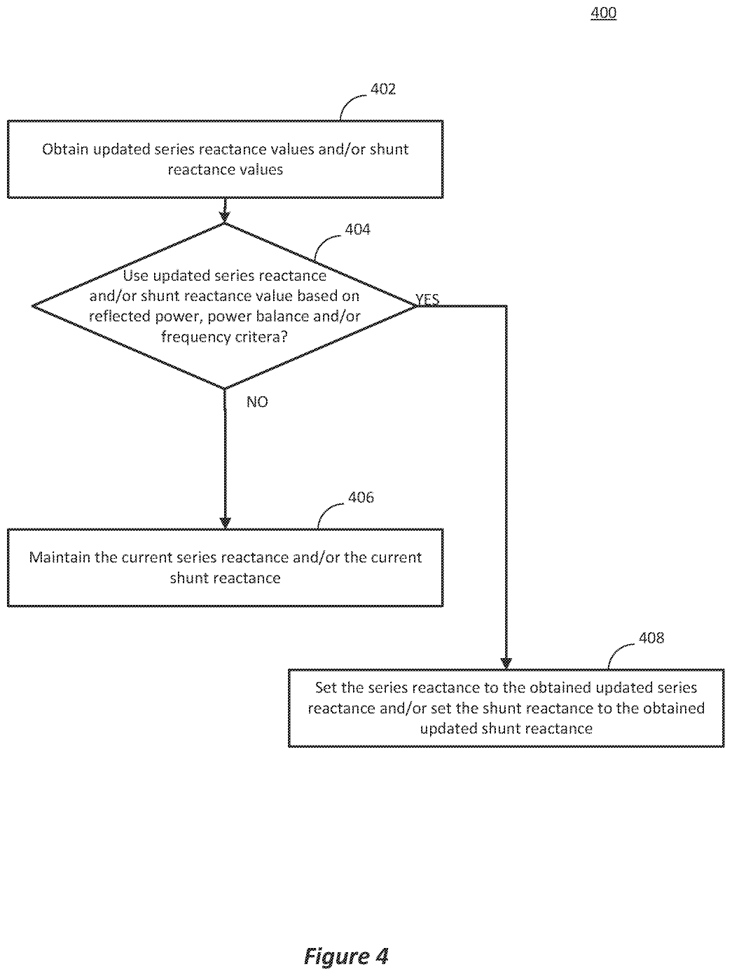

FIG. 4 shows a flowchart of an example process 400 for determining whether to use updated series reactance values and/or updated shunt reactance values in accordance with some implementations. It should be noted that blocks of process 400 may be executed by one or more processors and/or one or more controllers associated with the process chamber, as shown in and described above in connection with FIG. 1A. In some embodiments, blocks of process 400 may be performed in an order other than what is shown in FIG. 4. In some embodiments, two or more blocks of process 400 may be performed substantially in parallel. In some embodiments, one or more blocks of process 400 may be omitted. It should be noted that, in some implementations, process 400 may be performed after determining updated series reactance values and/or updated shunt reactance values (e.g., as described above in connection with block 308 of FIG. 3) and prior to adjusting series reactance elements and/or shunt reactance elements to achieve the updated series reactance values and/or shunt reactance values, respectively.

Process 400 can begin at 402 by obtaining updated series reactance values (X_{new_ser}(j), for a particular station j) and/or updated shunt reactance values (X_{new_shu}). For example, the updated series reactance values and/or the updated shunt reactance value may be those determined at block 308 of FIG. 3, as described above.

At 404, process 400 can determine whether to use the updated series reactance values and/or the updated shunt reactance value. For example, process 400 can determine that the updated series reactance values and/or the updated shunt reactance value are to be used responsive to determining that one or more criteria are met. In some implementations, the one or more criteria may include the measured station power ratio indicating a balance of power delivered to the stations of the process chamber exceeding a power balance threshold or being outside of a power balance range. The power balance threshold may be any suitable percentage (e.g., 0.1%, 0.5%, 1%, or the like) away from a power balance set point. In some implementations, the one or more criteria may include a metric indicating an amount of reflected power exceeding a reflected power threshold. For example, in instances in which the reflection coefficient is represented as Γ, the metric indicating reflected power may be |Γ|². In other words, the reflection coefficient is a complex value, and the metric indicating reflected power may be the square of the reflection coefficient magnitude The metric may indicate the ratio of reflected power to forward power delivered. Continuing with this example, the one or more criteria may be deemed as met if |Γ|² is greater than a reflected power threshold (e.g., 0.001, 0.005, 0.01, or the like). In some implementations, the one or more criteria may be based on an error associated with the second feedback control system exceeding an error threshold, where the error is a difference between measured frequencies and a target frequency. For example, the criteria may include an average of the frequencies at the one or more stations of the process chamber exceeding a frequency threshold (e.g., more than 0.1% away from the target frequency, more than 0.5% away from the target frequency, more than 1% away from the target frequency, or the like). Conversely, process 400 can determine that the updated series reactance values and/or the updated shunt reactance value are not to be used responsive to determining that none of the one or more criteria are met. It should be noted that, in some implementations a determination of whether to use the updated shunt reactance value may not consider criteria associated with power balance among different stations of the process chamber (e.g., in instances in which the shunt reactance is utilized for all stations of the process chamber, as shown in and described above in the example of FIG. 2).

If, at 404, process 400 determines the updated series reactance values and/or the updated shunt reactance value are not to be used (“no” at 404), process 400 can proceed to block 406 and can maintain the current series reactance value and/or the current shunt reactance value.

Conversely, if, at 404, process 400 determines the updated series reactance values and/or the updated shunt reactance value are to be used (“yes” at 404), process 400 can proceed to block 408, and can set the new series reactance value for each station to the updated series reactance value for the corresponding station, and/or can set the shunt reactance value to the updated shunt reactance value. The updated values may be used to adjust positions of variable reactance elements, such as variable capacitors.

It should be noted that, in some implementations, the updated series reactance values and/or the updated shunt reactance values may be modified or adjusted prior to being used. For example, if a difference between the updated reactance value and a present reactance value (whether a series reactance or a shunt reactance) is less than a dither threshold, the updated reactance values may be modified using the dither threshold. For example, the updated reactance values may be modified such that a change to the present reactance value is less than the dither threshold (e.g., half the dither threshold, or the like).

It should additionally be noted that, in some implementations, updated series reactance values may be considered separately from an updated shunt reactance value. For example, updated series reactance values may be modified based on a dither threshold while updated shunt reactance values are not modified based on the dither threshold, or vice versa.

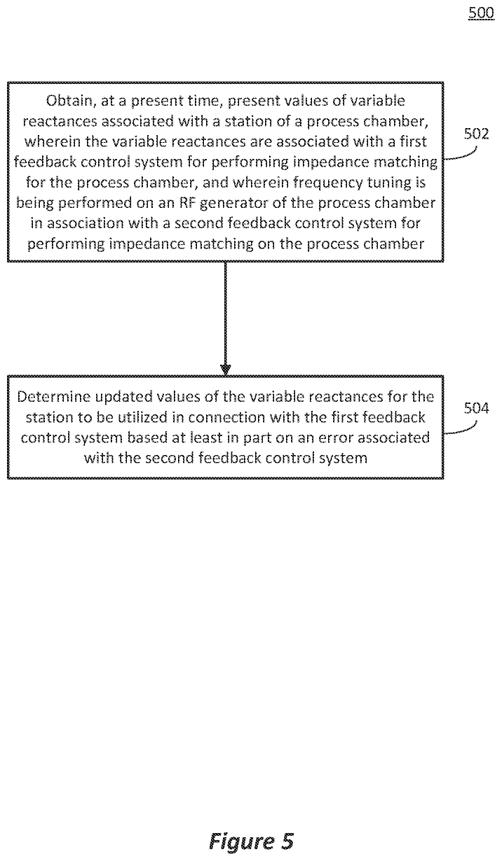

It should be noted that the processes described in connection with FIGS. 3 and 4 generally describe variable series reactances associated with each station of a process chamber, and a shunt reactance associated with all of the stations of the process chamber. Moreover, the variable reactance elements are generally described as variable capacitors. However, it should be understood that the techniques for coordinating a first feedback control system that utilizes variable reactances for impedance matching with a second feedback control system that performs frequency tuning for impedance matching may be applied with other configurations. FIG. 5 illustrates a flowchart of an example process 500 for coordinating a first feedback control system that utilizes variable reactances for impedance matching with a second feedback control system that performs frequency tuning for impedance matching in accordance with some embodiments. It should be noted that blocks of process 500 may be executed by one or more processors and/or one or more controllers associated with the process chamber, as shown in and described above in connection with FIG. 1A. In some embodiments, blocks of process 500 may be performed in an order other than what is shown in FIG. 5. In some embodiments, two or more blocks of process 500 may be performed substantially in parallel.

Process 500 may begin at 502 by obtaining, at a present time, present values of variable reactances associated with a station of a process chamber, wherein the variable reactances are associated with a first feedback control system for performing impedance matching for the process chamber, and wherein frequency tuning is being performed on an RF generator of the process chamber in association with a second feedback control system for performing impedance matching on the process chamber. It should be noted that the variable reactances may include any combination of series reactance elements and/or shunt reactance elements. Reactance elements may be associated with a particular station of the process chamber, or may be associated with all of the stations of the process chamber. Examples of variable reactance elements may include variable capacitors and/or variable inductors. A variable reactance element may be a vacuum variable capacitor that is actuated with a stepper motor. In some implementations, a variable reactance element may be a solid-state reactance element. In some implementations, the present values of the variable reactances may be determined using a calibration table or a look up table, as described above in connection with FIG. 3.

At 504, process 500 may determine updated values of the variable reactances for the station to be utilized in connection with the first feedback control system based at least in part on an error associated with the second feedback control system. For example, the error associated with the second feedback control system may be a difference between measured frequencies at the one or more stations (e.g., an average measured frequency across the one or more stations) and a target frequency, as described above in connection with FIG. 3. In some implementations, a frequency may be measured using a VI probe. In some implementations, a variable reactance may be determined based on a combination of the error associated with the second feedback control system and a target, or desired value of a variable reactance element. In some implementations, a target, or desired value of a variable reactance element may be determined based on a circuit model. In some implementations, a target, or desired value of the variable reactance element may be modified based on measured magnitude and/or phase information (e.g., measured using a VI probe), thereby compensating for errors or inaccuracies in the circuit model.

In some embodiments, modifying the variable reactance elements to have the updated values of the variable reactances may have the effect of minimizing or eliminating reflected power and balancing power delivered to the one or more stations of the process chamber. Moreover, modifying the variable reactance elements may cause the measured frequency at each station to be driven toward the target frequency.

### Context for Disclosed Computational Embodiments

Certain embodiments disclosed herein relate to computational systems for modulating voltages during plasma operations.

Many types of computing systems having any of various computer architectures may be employed as the disclosed systems for implementing algorithms as described herein. For example, the systems may include software components executing on one or more general purpose processors or specially designed processors such as Application Specific Integrated Circuits (ASICs) or programmable logic devices (e.g., Field Programmable Gate Arrays (FPGAs)). Further, the systems may be implemented on a single device or distributed across multiple devices. The functions of the computational elements may be merged into one another or further split into multiple sub-modules.

In some embodiments, code executed during generation or execution of a technique described herein on an appropriately programmed system can be embodied in the form of software elements which can be stored in a nonvolatile storage medium (such as optical disk, flash storage device, mobile hard disk, etc.), including a number of instructions for making a computer device (such as personal computers, servers, network equipment, etc.).

At one level a software element is implemented as a set of commands prepared by the programmer/developer. However, the module software that can be executed by the computer hardware is executable code committed to memory using “machine codes” selected from the specific machine language instruction set, or “native instructions,” designed into the hardware processor. The machine language instruction set, or native instruction set, is known to, and essentially built into, the hardware processor(s). This is the “language” by which the system and application software communicates with the hardware processors. Each native instruction is a discrete code that is recognized by the processing architecture and that can specify particular registers for arithmetic, addressing, or control functions; particular memory locations or offsets; and particular addressing modes used to interpret operands. More complex operations are built up by combining these simple native instructions, which are executed sequentially, or as otherwise directed by control flow instructions.

The inter-relationship between the executable software instructions and the hardware processor is structural. In other words, the instructions per se are a series of symbols or numeric values. They do not intrinsically convey any information. It is the processor, which by design was preconfigured to interpret the symbols/numeric values, which imparts meaning to the instructions.

The methods and techniques used herein may be configured to execute on a single machine at a single location, on multiple machines at a single location, or on multiple machines at multiple locations. When multiple machines are employed, the individual machines may be tailored for their particular tasks. For example, operations requiring large blocks of code and/or significant processing capacity may be implemented on large and/or stationary machines.

In addition, certain embodiments relate to tangible and/or non-transitory computer readable media or computer program products that include program instructions and/or data (including data structures) for performing various computer-implemented operations. Examples of computer-readable media include, but are not limited to, semiconductor memory devices, phase-change devices, magnetic media such as disk drives, magnetic tape, optical media such as CDs, magneto-optical media, and hardware devices that are specially configured to store and perform program instructions, such as read-only memory devices (ROM) and random access memory (RAM). The computer readable media may be directly controlled by an end user or the media may be indirectly controlled by the end user. Examples of directly controlled media include the media located at a user facility and/or media that are not shared with other entities. Examples of indirectly controlled media include media that is indirectly accessible to the user via an external network and/or via a service providing shared resources such as the “cloud.” Examples of program instructions include both machine code, such as produced by a compiler, and files containing higher level code that may be executed by the computer using an interpreter.

In various embodiments, the data or information employed in the disclosed methods and apparatus is provided in an electronic format. Such data or information may include various coefficients to be used in calculations, and the like. As used herein, data or other information provided in electronic format is available for storage on a machine and transmission between machines. Conventionally, data in electronic format is provided digitally and may be stored as bits and/or bytes in various data structures, lists, databases, etc. The data may be embodied electronically, optically, etc.

System software typically interfaces with computer hardware and associated memory. In some embodiments, the system software includes operating system software and/or firmware, as well as any middleware and drivers installed in the system. The system software provides basic non-task-specific functions of the computer. In contrast, the modules and other application software are used to accomplish specific tasks. Each native instruction for a module is stored in a memory device and is represented by a numeric value.

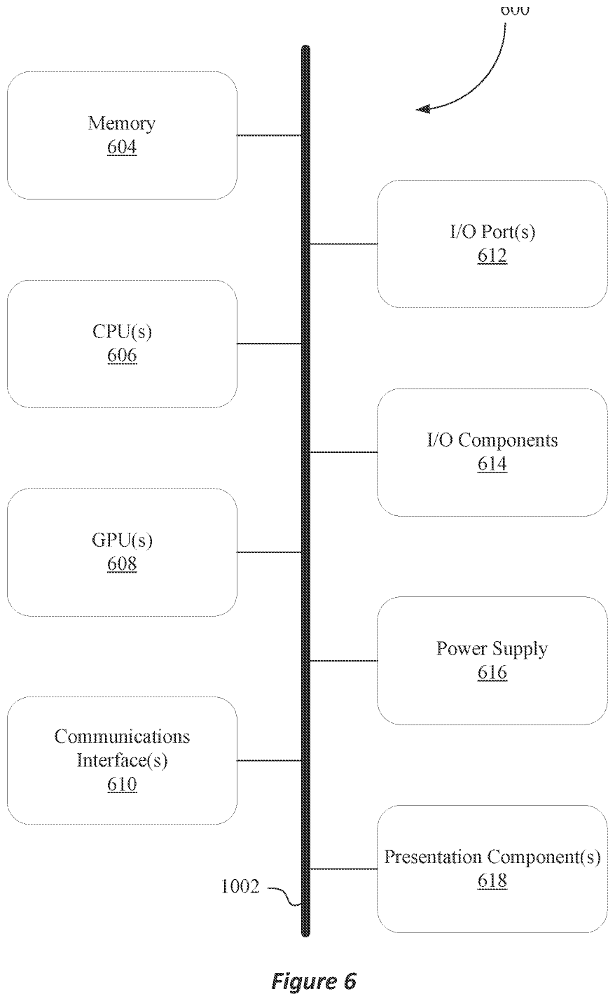

FIG. 6 is a block diagram of an example of the computing device 600 suitable for use in implementing some embodiments of the present disclosure. For example, device 600 may be suitable for implementing some or all functions of image analysis logic disclosed herein.

Computing device 600 may include a bus 602 that directly or indirectly couples the following devices: memory 604, one or more central processing units (CPUs) 606, one or more graphics processing units (GPUs) 608, a communication interface 1010, input/output (I/O) ports 612, input/output components 614, a power supply 616, and one or more presentation components 618 (e.g., display(s)). In addition to CPU 606 and GPU 608, computing device 600 may include additional logic devices that are not shown in FIG. 6, such as but not limited to an image signal processor (ISP), a digital signal processor (DSP), an ASIC, an FPGA, or the like.

Although the various blocks of FIG. 6 are shown as connected via the bus 602 with lines, this is not intended to be limiting and is for clarity only. For example, in some embodiments, a presentation component 618, such as a display device, may be considered an I/O component 614 (e.g., if the display is a touch screen). As another example, CPUs 606 and/or GPUs 608 may include memory (e.g., the memory 604 may be representative of a storage device in addition to the memory of the GPUs 608, the CPUs 606, and/or other components). In other words, the computing device of FIG. 6 is merely illustrative. Distinction is not made between such categories as “workstation,” “server,” “laptop,” “desktop,” “tablet,” “client device,” “mobile device,” “hand-held device,” “electronic control unit (ECU),” “virtual reality system,” and/or other device or system types, as all are contemplated within the scope of the computing device of FIG. 6.

Bus 602 may represent one or more busses, such as an address bus, a data bus, a control bus, or a combination thereof. The bus 1002 may include one or more bus types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, and/or another type of bus.

Memory 604 may include any of a variety of computer-readable media. The computer-readable media may be any available media that can be accessed by the computing device 600. The computer-readable media may include both volatile and nonvolatile media, and removable and non-removable media. By way of example, and not limitation, the computer-readable media may comprise computer-storage media and/or communication media.

The computer-storage media may include both volatile and nonvolatile media and/or removable and non-removable media implemented in any method or technology for storage of information such as computer-readable instructions, data structures, program modules, and/or other data types. For example, memory 1004 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which can be used to store the desired information and which can be accessed by computing device 1000. As used herein, computer storage media does not comprise signals per se.

The communication media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the communication media may include wired media such as a wired network or direct-wired connection, and wireless media such as acoustic, RF, infrared and other wireless media. Combinations of any of the above should also be included within the scope of computer-readable media.

CPU(s) 606 may be configured to execute the computer-readable instructions to control one or more components of the computing device 600 to perform one or more of the methods and/or processes described herein. CPU(s) 606 may each include one or more cores (e.g., one, two, four, eight, twenty-eight, seventy-two, etc.) that are capable of handling a multitude of software threads simultaneously. CPU(s) 606 may include any type of processor and may include different types of processors depending on the type of computing device 600 implemented (e.g., processors with fewer cores for mobile devices and processors with more cores for servers). For example, depending on the type of computing device 600, the processor may be an ARM processor implemented using Reduced Instruction Set Computing (RISC) or an x86 processor implemented using Complex Instruction Set Computing (CISC). Computing device 600 may include one or more CPUs 606 in addition to one or more microprocessors or supplementary co-processors, such as math co-processors.

GPU(s) 608 may be used by computing device 600 to render graphics (e.g., 3D graphics). GPU(s) 608 may include many (e.g., tens, hundreds, or thousands) of cores that are capable of handling many software threads simultaneously. GPU(s) 608 may generate pixel data for output images in response to rendering commands (e.g., rendering commands from CPU(s) 606 received via a host interface). GPU(s) 608 may include graphics memory, such as display memory, for storing pixel data. The display memory may be included as part of memory 604. GPU(s) 608 may include two or more GPUs operating in parallel (e.g., via a link). When combined, each GPU 608 can generate pixel data for different portions of an output image or for different output images (e.g., a first GPU for a first image and a second GPU for a second image). Each GPU can include its own memory or can share memory with other GPUs.

In examples where the computing device 600 does not include the GPU(s) 608, the CPU(s) 606 may be used to render graphics.

Communication interface 610 may include one or more receivers, transmitters, and/or transceivers that enable computing device 600 to communicate with other computing devices via an electronic communication network, included wired and/or wireless communications. Communication interface 610 may include components and functionality to enable communication over any of a number of different networks, such as wireless networks (e.g., Wi-Fi, Z-Wave, Bluetooth, Bluetooth LE, ZigBee, etc.), wired networks (e.g., communicating over Ethernet), low-power wide-area networks (e.g., LoRaWAN, SigFox, etc.), and/or the internet.

I/O ports 612 may enable the computing device 600 to be logically coupled to other devices including I/O components 614, presentation component(s) 618, and/or other components, some of which may be built in to (e.g., integrated in) computing device 600. Illustrative I/O components 614 include a microphone, mouse, keyboard, joystick, track pad, satellite dish, scanner, printer, wireless device, etc. I/O components 614 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of computing device 600. Computing device 600 may be include depth cameras, such as stereoscopic camera systems, infrared camera systems, RGB camera systems, touchscreen technology, and combinations of these, for gesture detection and recognition. Additionally, computing device 600 may include accelerometers or gyroscopes (e.g., as part of an inertia measurement unit (IMU)) that enable detection of motion. In some examples, the output of the accelerometers or gyroscopes may be used by computing device 600 to render immersive augmented reality or virtual reality.

Power supply 616 may include a hard-wired power supply, a battery power supply, or a combination thereof. Power supply 616 may provide power to computing device 600 to enable the components of computing device 600 to operate.

Presentation component(s) 618 may include a display (e.g., a monitor, a touch screen, a television screen, a heads-up-display (HUD), other display types, or a combination thereof), speakers, and/or other presentation components. Presentation component(s) 618 may receive data from other components (e.g., GPU(s) 608, CPU(s) 606, etc.), and output the data (e.g., as an image, video, sound, etc.).

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to code that perform particular tasks or implement particular abstract data types. The disclosure may be practiced in a variety of system configurations, including hand-held devices, consumer electronics, general-purpose computers, more specialty computing devices, etc. The disclosure may also be practiced in distributed computing environments where tasks are performed by remote-processing devices that are linked through a communications network.

### CONCLUSION

In the description, numerous specific details were set forth in order to provide a thorough understanding of the presented embodiments. The disclosed embodiments may be practiced without some or all of these specific details. In other instances, well-known process operations were not described in detail to not unnecessarily obscure the disclosed embodiments. While the disclosed embodiments were described in conjunction with the specific embodiments, it will be understood that the specific embodiments are not intended to limit the disclosed embodiments.

Unless otherwise indicated, the method operations and device features disclosed herein involves techniques and apparatus commonly used in metrology, semiconductor device fabrication technology, software design and programming, and statistics, which are within the skill of the art.

Unless defined otherwise herein, all technical and scientific terms used herein have the same meaning as commonly understood by one of ordinary skill in the art. Various scientific dictionaries that include the terms included herein are well known and available to those in the art. Although any methods and materials similar or equivalent to those described herein find use in the practice or testing of the embodiments disclosed herein, some methods and materials are described.

Numeric ranges are inclusive of the numbers defining the range. It is intended that every maximum numerical limitation given throughout this specification includes every lower numerical limitation, as if such lower numerical limitations were expressly written herein. Every minimum numerical limitation given throughout this specification will include every higher numerical limitation, as if such higher numerical limitations were expressly written herein. Every numerical range given throughout this specification will include every narrower numerical range that falls within such broader numerical range, as if such narrower numerical ranges were all expressly written herein.

The headings provided herein are not intended to limit the disclosure.

As used herein, the singular terms “a,” “an,” and “the” include the plural reference unless the context clearly indicates otherwise. The term “or” as used herein, refers to a non-exclusive or, unless otherwise indicated.

Various computational elements including processors, memory, instructions, routines, models, or other components may be described or claimed as “configured to” perform a task or tasks. In such contexts, the phrase “configured to” is used to connote structure by indicating that the component includes structure (e.g., stored instructions, circuitry, etc.) that performs the task or tasks during operation. As such, the unit/circuit/component can be said to be configured to perform the task even when the specified component is not necessarily currently operational (e.g., is not on).

The components used with the “configured to” language may refer to hardware—for example, circuits, memory storing program instructions executable to implement the operation, etc. Additionally, “configured to” can refer to generic structure (e.g., generic circuitry) that is manipulated by software and/or firmware (e.g., an FPGA or a general-purpose processor executing software) to operate in manner that is capable of performing the recited task(s). Additionally, “configured to” can refer to one or more memories or memory elements storing computer executable instructions for performing the recited task(s). Such memory elements may include memory on a computer chip having processing logic. In some contexts, “configured to” may also include adapting a manufacturing process (e.g., a semiconductor fabrication facility) to fabricate devices (e.g., integrated circuits) that are adapted to implement or perform one or more tasks.

1. A computer program product for an impedance matching and power distribution network, the computer program product comprising a non-transitory computer readable medium on which is provided computer-executable instructions for:
obtaining, at a present time, present values of variable reactances associated with a station of a process chamber, wherein the variable reactances are associated with a first feedback control system for performing impedance matching for the process chamber, and wherein frequency tuning is being performed on an RF generator of the process chamber in association with a second feedback control system for performing impedance matching for the process chamber; and
determining updated values of the variable reactances for the station to be utilized in connection with the first feedback control system based at least in part on an error associated with the second feedback control system.

2. The computer program product of claim 1, wherein the error associated with the second feedback control system comprises a difference between a measured frequency at the station and a target frequency associated with the process chamber.

3. The computer program product of claim 2, wherein the frequency at the station is determined using one or more sensing circuits.

4. The computer program product of claim 1, wherein the updated values of the variable reactances are usable to modify positions of one or more variable reactance elements associated with the process chamber to minimize reflected power associated with the station.

5. The computer program product of claim 4, wherein the one or more variable reactance elements comprise at least one of: a series capacitor, or a shunt capacitor.

6. The computer program product of claim 4, wherein modifying the positions of the one or more variable reactance elements associated with the first feedback control system causes the second feedback control system to drive the frequency toward a target frequency.

7. The computer program product of claim 6, wherein the target frequency corresponds to a frequency specified for a step of a recipe performed at the present time.

8. The computer program product of claim 1, wherein the computer-executable instructions are further configured for determining positions of one or more variable reactance elements using a calibration table and based at least in part on the updated values of the variable reactances.

9. The computer program product of claim 1, wherein the variable reactances comprise a series reactance associated with the station of the process chamber.

10. The computer program product of claim 1, wherein the variable reactances comprise a shunt reactance associated with the process chamber.

11. The computer program product of claim 1, wherein the variable reactances comprise a variable series reactance, and wherein an updated series reactance is determined based on a correction to a target series reactance, wherein the correction incorporates the error associated with the second feedback control system.

12. The computer program product of claim 1, wherein the variable reactances comprise a variable shunt reactance, and wherein an updated shunt reactance is determined without determining a target shunt reactance and based at least in part on the error associated with the second feedback control system.

13. The computer program product of claim 1, wherein the updated values of the variable reactances are utilized by the first feedback control system responsive to one or more criteria being met.

14. The computer program product of claim 13, wherein the one or more criteria comprise: a reflected power associated with the process chamber exceeding a reflected power threshold, a power balance ratio associated with a plurality of stations of the process chamber exceeding a power balance threshold, and the error associated with the second feedback control system exceeding an error threshold.

15. The computer program product of claim 13, wherein the updated values of the variable reactances are modified prior to use responsive to a determination that a difference between the present values of the variable reactances and the updated values of the variable reactances are within a dither threshold.

16. The computer program product of claim 1, wherein the determining the updated values of the variable reactances for the station based at least in part on the error associated with the second feedback control system is responsive to a determination that a mode associated with controlling the first feedback control system based on the error associated with the second feedback control system has been activated in a recipe being utilized at the present time.

17. A method for impedance matching and power distribution comprising:
obtaining, at a present time, present values of variable reactances associated with a station of a process chamber, wherein the variable reactances are associated with a first feedback control system for performing impedance matching for the process chamber, and wherein frequency tuning is being performed on an RF generator of the process chamber in association with a second feedback control system for performing impedance matching for the process chamber; and
determining updated values of the variable reactances for the station to be utilized in connection with the first feedback control system based at least in part on an error associated with the second feedback control system.

18. The method of claim 17, wherein the error associated with the second feedback control system comprises a difference between a measured frequency at the station and a target frequency associated with the process chamber.

19. The method of claim 18, wherein the frequency at the station is determined using one or more sensing circuits.

20. The method of claim 17, wherein the updated values of the variable reactances are usable to modify positions of one or more variable reactance elements associated with the process chamber to minimize reflected power associated with the station.
